(19) United States
(12) Patent Application Publication
(10) Pub. No.: US 2024/0105671 A1
(43) Pub. Date: Mar. 28, 2024

(54) APPARATUS FOR TRANSFERRING ELECTRONIC COMPONENT AND METHOD FOR BONDING ELECTRONIC COMPONENT

(71) Applicant: Stroke Precision Advanced Engineering Co., Ltd., Taoyuan City (TW)

(72) Inventors: Chien-Shou Liao, Taichung City (TW); Chingju Lin, Taoyuan City (TW)

(73) Assignee: Stroke Precision Advanced Engineering Co., Ltd., Taoyuan City (TW)

(21) Appl. No.: 18/447,320

(22) Filed: Aug. 10, 2023

(30) Foreign Application Priority Data
Sep. 27, 2022 (TW) 111136456

(51) Int. Cl. H01L 23/00; H01L 25/16

(52) U.S. Cl. CPC H01L 24/75; H01L 24/81; H01L 25/167; H01L 2224/75262; H01L 2224/75314; H01L 2224/7555; H01L 2224/81005; H01L 2224/81201; H01L 2224/81224; H01L 2224/81815

(57) ABSTRACT

An apparatus for transferring an electronic component including a first platform, a second platform, an actuator mechanism, and a flexible push generator is provided. The first platform is configured to carry a carrier substrate. The second platform is configured to carry a target substrate. The actuator mechanism is configured to actuate the first platform and the second platform to approach and move away from each other. The flexible push generator is disposed near the first platform or the second platform and generating a plurality of flexible pushes toward the first platform and the second platform in response to the first platform and the second platform actuated in a way that the first platform and the second platform approach each other.

### CROSS-REFERENCE TO RELATED APPLICATION

This application claims the priority benefit of Taiwan application serial no. 111136456, filed on Sep. 27, 2022. The entirety of the above-mentioned patent application is hereby incorporated by reference herein and made a part of this specification.

### BACKGROUND

### Technical Field

The disclosure relates to an apparatus and a method, and more particularly, to an apparatus for transferring an electronic component and a method for bonding an electronic component.

### Description of Related Art

In the manufacturing process of electronic products, there are often related transfer steps. For example, in the manufacturing process of LED displays, light-emitting diodes are often placed on a TFT array substrate by a pick-and-place apparatus first. However, with the pick-and-place apparatus or the transfer step, it may be more difficult to bring the transferred objects closer together.

### SUMMARY

The disclosure provides an apparatus for transferring an electronic component and a method for bonding an electronic component, which may at least cause the corresponding carrier substrate and target substrate to approach each other.

An apparatus for transferring an electronic component of the disclosure includes a first platform, a second platform, an actuator mechanism, and a flexible push generator. The first platform is configured to carry a carrier substrate. The second platform is configured to carry a target substrate. The actuator mechanism is configured to actuate the first platform and the second platform to approach and move away from each other. The flexible push generator is disposed near the first platform or the second platform and generating a plurality of flexible pushes toward the first platform and the second platform in response to the first platform and the second platform actuated in a way that the first platform and the second platform approach each other.

A method for bonding an electronic component of the disclosure includes the following steps: providing a carrier substrate having a carrying surface on which the electronic component to be bonded is disposed and a non-carrying surface which is opposite to the carrying surface; providing a target substrate having a bonded surface and a non-bonded surface which is opposite to the bonded surface; positioning the carrier substrate and the target substrate with the carrying surface of the carrier substrate facing the bonded surface of the target substrate; making the carrier substrate and the target substrate move toward each other until the electronic component on the carrying surface of the carrier substrate be in contact with the bonded surface of the target substrate; applying a plurality of flexible pushes to the non-carrying surface of the carrier substrate or to the non-bonded surface of the target substrate, in order for the electronic component on the carrying substrate to attain a more complete contact with the bonded surface of the target substrate; and applying a thermal energy to bond the electronic component onto the bonded surface of the target substrate from the carrier substrate.

Based on the above, in the apparatus for transferring the electronic component and the method for bonding the electronic component of the disclosure, multiple flexible pushes may at least cause the corresponding carrier substrate and target substrate to approach each other.

### BRIEF DESCRIPTION OF THE DRAWINGS

FIG. 1 to FIG. 4 are partial schematic side views of an apparatus for transferring an electronic component or a method for bonding an electronic component according to an embodiment of the disclosure.

FIG. 5 is a partial schematic side view of an apparatus for transferring an electronic component or a method for bonding an electronic component according to an embodiment of the disclosure.

FIG. 6 is a partial schematic top view of an apparatus for transferring an electronic component according to an embodiment of the disclosure.

FIG. 7A is a partial schematic view of the connection of components in an apparatus for transferring an electronic component according to an embodiment of the disclosure.

FIG. 7B is a partial schematic view of the connection of components in an apparatus for transferring an electronic component according to an embodiment of the disclosure.

### DESCRIPTION OF THE EMBODIMENTS

The content of the following embodiments is for illustration rather than limitation. Moreover, the description of well-known devices, methods, and materials may be omitted so as not to obscure the description of the various principles of the disclosure. Directional terms (e.g., up and down) used herein only refer to the graphical use or corresponding normal terminologies, and are not intended to imply absolute orientation. Thus, unless otherwise specified, the directional terms are used to illustrate rather than limit the disclosure. Furthermore, in order to clearly indicate the directional relationship between different drawings, a Cartesian coordinate system (XYZ coordinate system) is exemplarily used in some of the diagrams to represent the corresponding directions, but the disclosure is not limited thereto.

In addition, singular forms such as “one,” “a,” “the,” or forms without specifying quantity may include one or more, that is, they may include “at least one” unless the context clearly indicates otherwise.

In some of the drawings, for the sake of clarity, certain components or layers may be enlarged, reduced, or omitted. Similar components are denoted by the same reference numerals, and have similar functions, materials, or forming methods, and the description is omitted. It will be obvious to those with ordinary knowledge in the art to which the disclosure pertains, based on the content of the embodiments and the corresponding illustrations, the disclosure can be practiced in other embodiments that deviate from the specific details disclosed in this document.

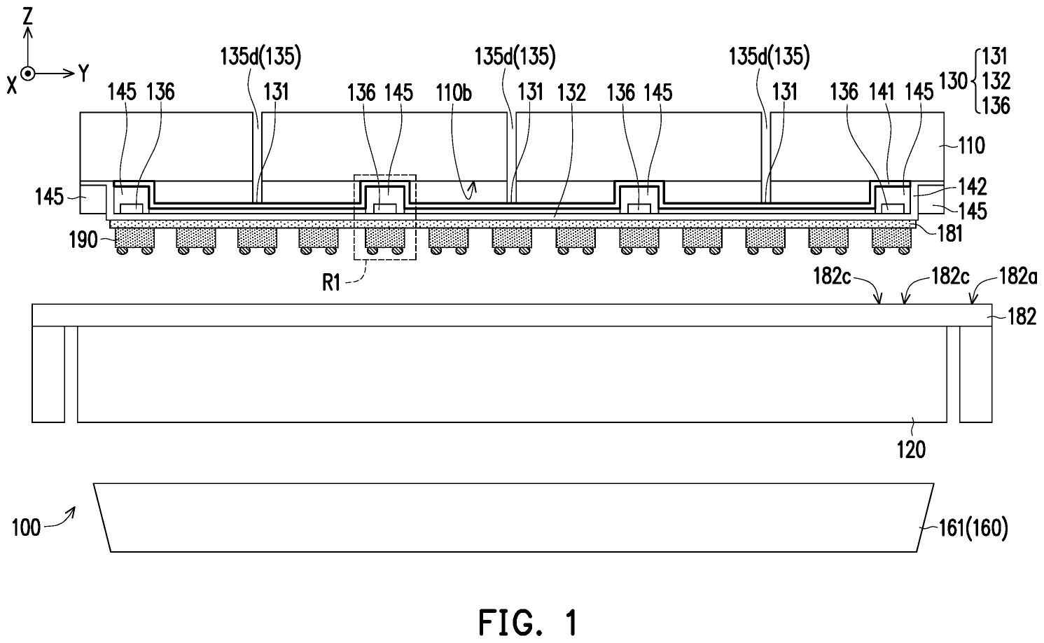

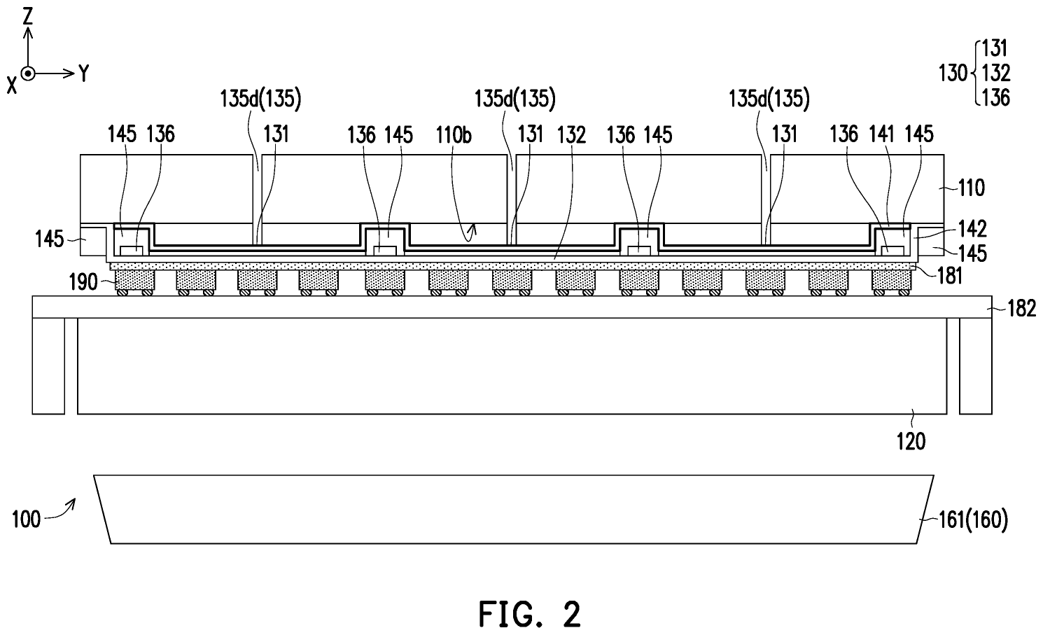

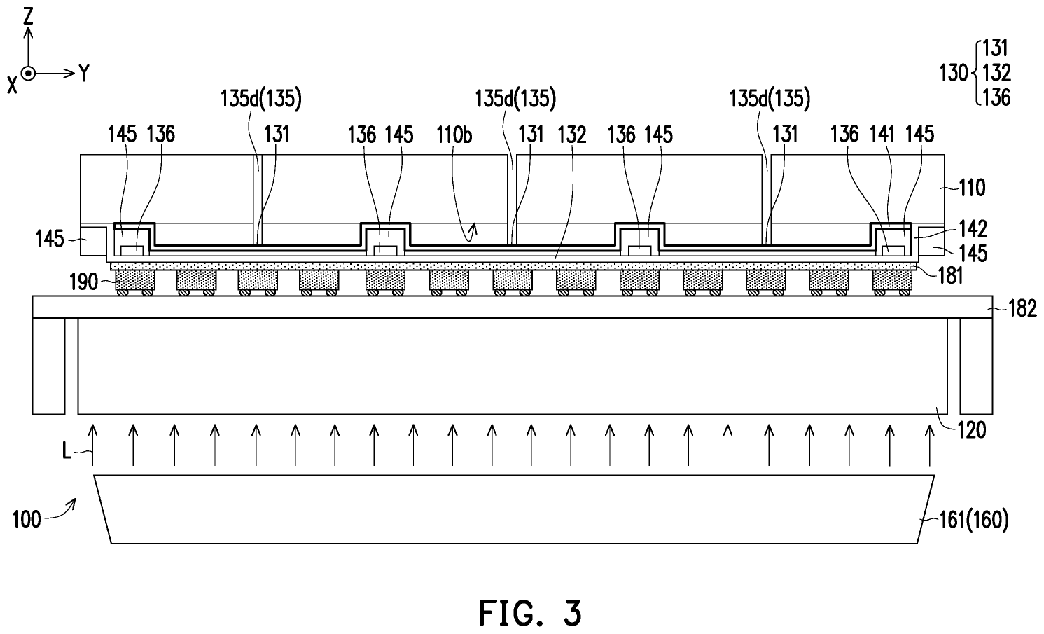

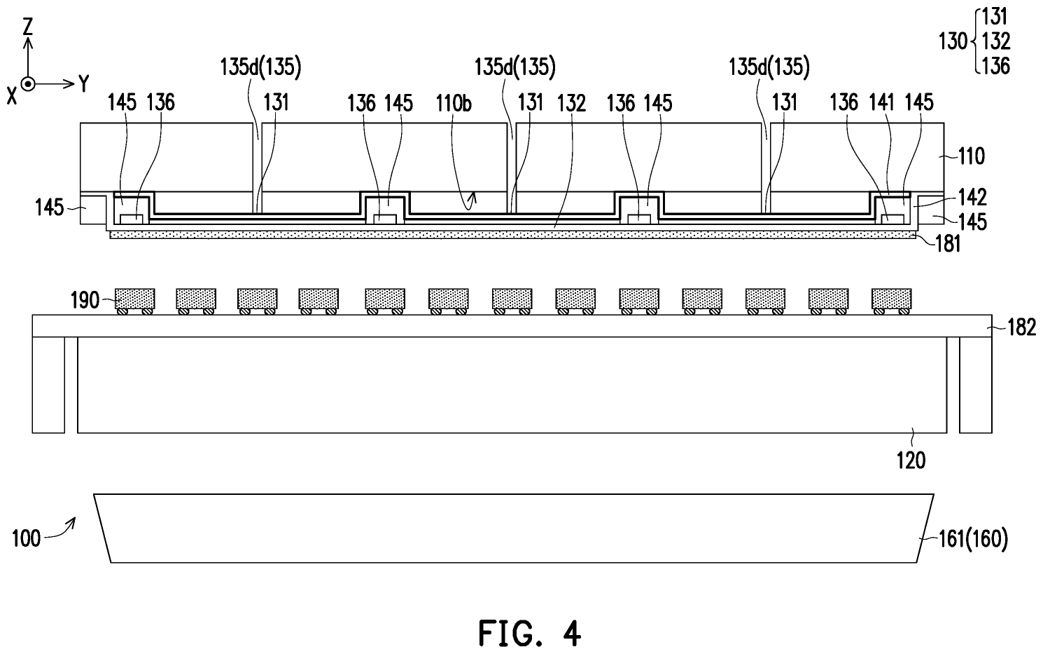

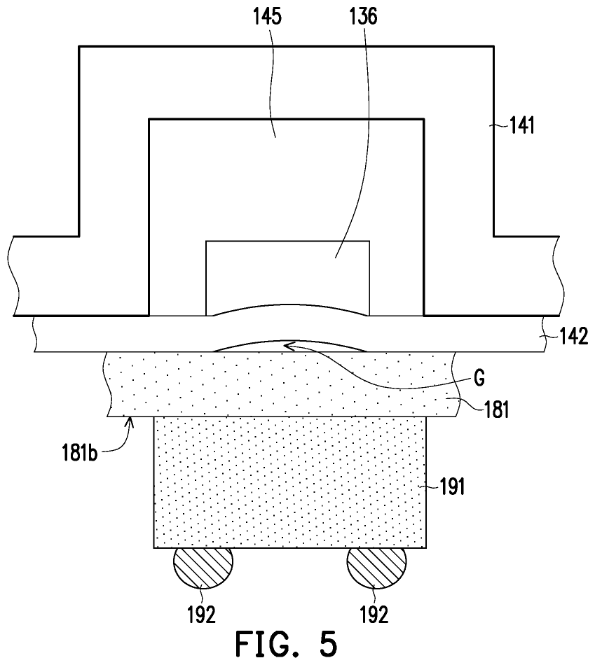

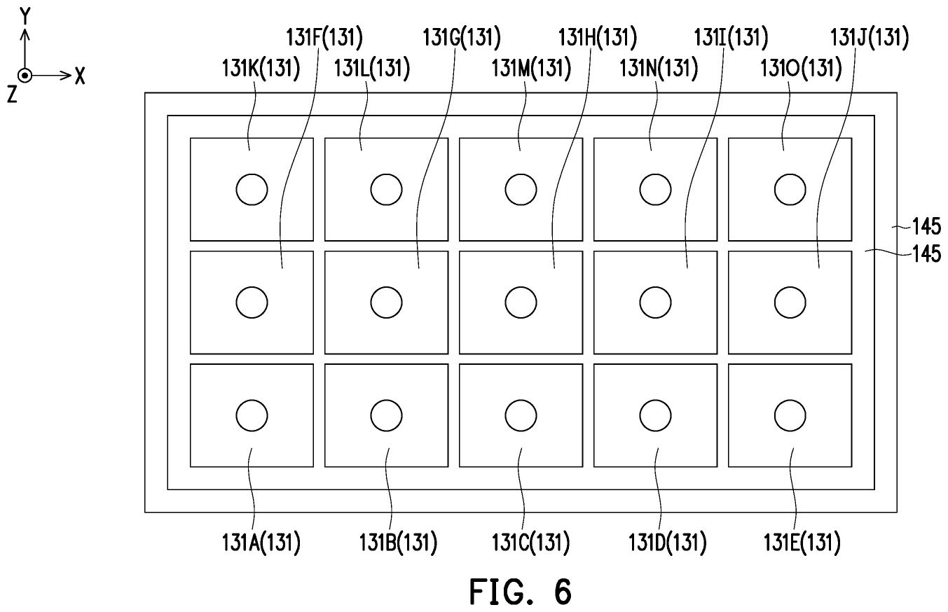

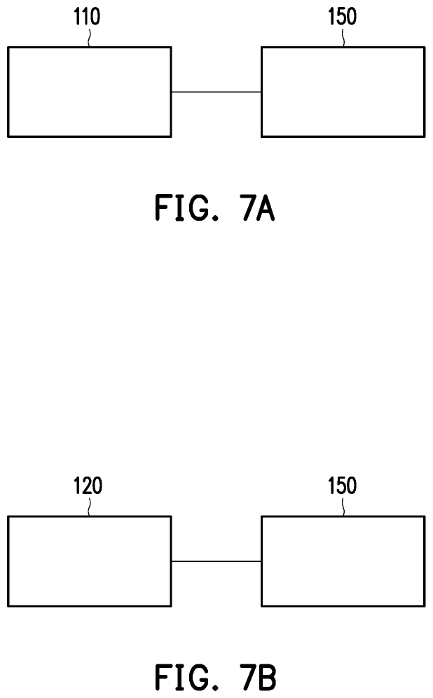

FIG. 1 to FIG. 4 are partial schematic side views of an apparatus for transferring an electronic component or a method for bonding an electronic component according to an embodiment of the disclosure. FIG. 5 is a partial schematic side view of an apparatus for transferring an electronic component or a method for bonding an electronic component according to an embodiment of the disclosure. For example, FIG. 5 may be an enlarged view corresponding to region R1 in FIG. 1. FIG. 6 is a partial schematic top view of an apparatus for transferring an electronic component according to an embodiment of the disclosure. For example, FIG. 6 may be a schematic top view corresponding to FIG. 1, FIG. 2, FIG. 3, and/or FIG. 4. FIG. 7A is a partial schematic view of the connection of components in an apparatus for transferring an electronic component according to an embodiment of the disclosure. FIG. 7B is a partial schematic view of the connection of members in an apparatus for transferring an electronic component according to an embodiment of the disclosure.

Referring to FIG. 1, an apparatus 100 may be used to transfer an electronic component 190. The apparatus 100 includes a first platform 110, a second platform 120, an actuator mechanism 150 (marked in FIG. 7A or FIG. 7B), and a flexible push generator (which may be referred as a flexible push generating mechanism) 130. The first platform 110 may be configured to carry a carrier substrate 181. The second platform 120 may be configured to carry a target substrate 182. The actuator mechanism 150 may actuate the first platform 110 and the second platform 120 to approach and move away from each other. The flexible push generator 130 may be disposed near the first platform 110 or the second platform 120. Multiple flexible pushes are generated by the flexible push generator 130 in a direction of the first platform 110 and the second platform 120 in response to the actuator mechanism 150 causing the first platform 110 and the second platform 120 to approach each other. In addition, for the sake of clarity, not all electronic components 190 are individually marked in FIG. 1 or similar drawings.

In an embodiment, as shown in FIG. 7A, the first platform 110 may be movably connected to the actuator mechanism 150; and/or, as shown in FIG. 7B, the second platform 120 may be movably connected to the actuator mechanism 150. The actuator mechanism 150 includes, for example, corresponding motors, gears, transmission belts, transmission chains, threaded rods, or other members suitable for moving the first platform 110 and/or the second platform 120. In this way, by actuating the actuator mechanism 150, the first platform 110 is moved toward the second platform 120, and/or the second platform 120 is moved toward the first platform 110.

In an embodiment, a surface 110b of the first platform 110 (at the bottom of FIG. 1 or other similar figures) may have a corresponding flexible film (e.g., a first flexible film 141 or a second flexible film 142). A portion of the flexible film may be fixed on the surface 110b of the first platform 110 through a corresponding ring fastener 145. The fastener 145 may be a single member; or, one or more fasteners, one or more clips, one or more pledges, one or more locks, and/or a combination of the foregoing. A space between a region of the flexible film surrounded by the fastener 145 and the first platform 110 may be connected with an appropriate gas pipeline. Thus, if the space is inflated with gas through the gas pipeline, the atmospheric pressure in the space may be increased and/or the space may be expanded. Conversely, if the gas pipeline pumps air out of the space, the atmospheric pressure in the space may be reduced and/or the space may be reduced. In this way, a corresponding air bag may be formed by the above method. For example, the flexible film 141 may form a portion of a first air bag 131; and/or, the flexible film 142 may form a portion of a second air bag 132.

In an embodiment, the flexible push generator 130 may include a vent device 136. The vent device 136 may be connected to an air pump through an appropriate gas pipeline. The carrier substrate 181 may be carried on the first platform 110 by the air extraction of the air pump. The gas pipeline may include corresponding valves that may adjust the flow capacity or flow velocity of the gas.

For example, referring to FIG. 5, the vent device 136 may be placed on a flexible film 142 (e.g., a portion of the second air bag 132). The atmospheric pressure of a gap G between the flexible film 142 and the carrier substrate 181 may be made lower than the ambient atmospheric pressure by air extraction of the air pump. In this way, the carrier substrate 181 may be carried on the first platform 110 (at the bottom of FIG. 1 or other similar figures). In addition, the vent device 136 in the air extraction state may be referred to as an air extracting device.

In an embodiment, the electronic component 190 may be adhered to a surface 181b of the carrier substrate 181 (at the bottom of FIG. 1 or other similar figures). The electronic component 190 may be transferred by the subsequent process. That is, the electronic component 190 may be temporarily adhered to the surface 181b of the carrier substrate 181 (at the bottom of FIG. 1 or other similar figures). For example, a release film (not shown) may be provided between the surface 181b of the carrier substrate 181 and the electronic component 190, but the disclosure is not limited thereto.

In an embodiment, the electronic component 190 may include a light-emitting diode (LED) chip.

In an embodiment, a corresponding bonded position 182c may be provided on the bonded surface 182a of the target substrate 182 (at the top of FIG. 1 or other similar figures). The bonded position 182c of the target substrate 182 may correspond to the electronic component 190. For example, the bonded position 182c of the target substrate 182 may correspond to a solder 192 on the electronic component 190. In addition, for the sake of clarity, not all bonding positions 182c are individually marked in FIG. 1 or other similar drawings; or, some or all of the bonding positions 182c may be omitted.

In an embodiment, the electronic component 190 may be applied a solder 192 (marked in FIG. 5). In an embodiment not shown, a solder that is the same or similar to the solder 192 may be applied to the bonding position 182c of the target substrate 182.

In an embodiment, the target substrate 182 may have a corresponding circuit (not shown). For example, the bonding position 182c of the target substrate 182 may have a corresponding contact pad. In an embodiment, the target substrate 182 may include a thin film transistor (TFT) substrate.

Referring to FIG. 1 to FIG. 2, the surface 18 lb of the carrier substrate 181, on which the electronic component 190 is adhered, is positioned opposite the surface 182a of the target substrate 182 having the bonding position 182c, and the carrier substrate 181 and the target substrate 182 are actuated to approach each other until the electronic component 190 is in contact with the bonding position 182c. For example, the surface 181b of the carrier substrate 181, on which the electronic component 190 is adhered, and the bonded surface 182a of the target substrate 182 having the bonded position 182c are made face to face. Afterwards, the actuator mechanism 150 may be used to actuate the carrier substrate 181 and the target substrate 182 to approach each other until the solder 192 on the electronic component 190 is in contact with the bonded position 182c on the target substrate 182.

In an embodiment, multiple flexible pushes are generated in a direction of the first platform 110 and the second platform 120 in response to the actuator mechanism 150 causing the first platform 110 and the second platform 120 to approach each other. For example, the flexible push generator 130 may include a first air bag 131 and an inflating device 135. The inflating device 135 may include, for example, a corresponding inflating pump and a corresponding gas pipeline 135d. The gas pipeline 135d may be connected to the inflating pump and the first air bag 131. In this way, the corresponding first air bag 131 may be inflated by the inflating device 135 to generate the corresponding flexible push.

In an embodiment, the amount of the first air bag 131 may be plural. For example, as shown in FIG. 6, the first air bag 131 may include a first air bag 131A, a first air bag 131B, a first air bag 131C, a first air bag 131D, a first air bag 131E, a first air bag 131F, a first air bag 131G, a first air bag 131H, a first air bag 1311, a first air bag 131J, a first air bag 131K, a first air bag 131L, a first air bag 131M, a first air bag 131N, and a first air bag 1310. There is no specific limitation on the amount of the first air bag 131 in the disclosure, as long as it is plural.

In one direction, multiple first air bags of the first air bags 131 may be arranged side by side. For example, in a first direction X, the first air bag 131A, the first air bag 131B, the first air bag 131C, the first air bag 131D, and the first air bag 131E may be arranged side by side. In an embodiment, the first air bags 131 may be arranged in an array.

In an embodiment, the order for inflating the corresponding first air bag 131 may be applied sequentially and/or separately from one lateral side of the carrier substrate 181 or the target substrate 182 to another lateral side opposite the lateral side. For example, the plurality of flexible pushes are applied from a side of the non-carrying surface of the carrier substrate 181 or of the non-bonded surface of the target substrate 182 to an opposite side opposite to the side of the non-carrying surface of the carrier substrate 181 or of the non-bonded surface of the target substrate 182.

For example, further referring to FIG. 6, the first air bags 131A, 131F, and 131K may be inflated; next, the first air bags 131B, 131G, and 131L may be inflated; next, the first air bags 131C, 131H, and 131M may be inflated; next, the first air bags 131D, 1311, and 131N may be inflated; next, the first air bags 131E, 131J, and 1310 may be inflated. In short, along the first direction X, the corresponding first air bag 131 may be inflated sequentially and/or respectively.

For example, further referring to FIG. 6, the first air bags 131A, 131B, 131C, 131D, and 131E may be inflated; next, the first air bags 131F, 131G, 131H, 1311, and 131J may be inflated; next, the first air bags 131K, 131L, 131M, 131N, and 1310 may be inflated. In short, along a second direction Y, the corresponding first air bag 131 may be inflated sequentially and/or respectively.

In an embodiment, the order for inflating the corresponding first air bag 131 may be applied sequentially and/or respectively from one corner of the carrier substrate 181 or the target substrate 182 to another corner opposite the corner.

For example, further referring to FIG. 6, the first air bag 131A may be inflated; next, the first air bags 131B and 131F may be inflated; next, the first air bags 131C, 131G, and 131K may be inflated; next, the first air bags 131D, 131H, and 131L may be inflated; next, the first air bags 131E, 1311, and 131M may be inflated; next, the first air bags 131J and 131N may be inflated; next, the first air bag 1310 may be inflated.

In an embodiment, the order for inflating the corresponding first air bag 131 may be applied sequentially and/or respectively outward from a central position of the carrier substrate 181 or target substrate 182. For example, the plurality of flexible pushes are applied outward from a central portion of the non-carrying surface of the carrier substrate 181 or of the non-bonded 20 surface of the target substrate 182.

For example, further referring to FIG. 6, the first air bag 131H may be inflated; next, the first air bags 131B, 131C, 131D, 131G, 1311, 131L, 131M, and 131N may be inflated; next, the first air bags 131A, 131F, 131K, 131E, 131J, and 1310 may be inflated.

In an embodiment, the carrier substrate 181 and the target substrate 182 may be caused to approach each other by inflating the first air bag 131 as described above; and/or, the flatness of the carrier substrate 181 and/or the target substrate 182 may be increased after the electronic component 190 is in contact with the bonding position 182c.

Reference to FIG. 2, the flexible push generator 130 may further include a second air bag (which may be referred as a cover air bag) 132 wrapping or enclosing the first air bags 131. After applying the flexible pushes by the first air bags 131, by further inflating the second air bag 132, the second air bag 132 may generate a flexible push applied to the carrier substrate 181 and/or the target substrate 182, causing the carrier substrate 181 and the target substrate 182 to approach each other; and/or, the flatness of the carrier substrate 181 and/or the target substrate 182 may be increased after the electronic component 190 is in contact with the bonding position 182c.

For example, the vent device 136 may be connected to the air pump (not shown) through an appropriate gas pipeline (not shown). The second air bag 132 may be inflated by the air pump. The vent device 136 in the air inflating state may be referred to as an inflating device 135. For another example, the way to inflate the second air bag 132 may be similar to the way to inflate the first air bag 131.

It should be noted that at this moment (e.g., the state shown in FIG. 2), basically, the electronic component 190 is not bonded to the bonded position 182c of the target substrate 182.

Referring to FIG. 2 to FIG. 3, by applying the flexible pushes through the first air bags 131 and/or the second air bag 132, after the carrier substrate 181 and the target substrate 182 are caused to approach each other (e.g., the state shown in FIG. 2), thermal energy may be applied through a thermal energy generator 160 as shown in FIG. 3. The solder 192 may be melted with sufficient thermal energy. In this way, the electronic component 190 may be bonded to and fixed on the bonded position 182c of the target substrate 182 after the application of the thermal energy is stopped and the molten solder 192 is cooled.

In an embodiment, the thermal energy generator 160 may include a laser generator 161. The laser generator 161 may be disposed near the first platform 110 or the second platform 120. In addition, the laser generator 161 may generate a laser beam L toward the first platform 110 and the second platform 120.

In an embodiment, the laser beam L may further irradiate the release film (if any) between the carrying surface 181b of the carrier substrate 181 and the electronic component 190; alternatively, the thermal energy may be heat-conducted to the release film (if any) between the carrying surface 18 lb of the carrier substrate 181 and the electronic component 190. The release film (if any) may lose viscosity or binding force when exposed to light and/or heat. In this way, the electronic component 190 may be easily separated from the carrier substrate 181 in subsequent process.

Taking FIG. 3 as an example, the laser generator 161 may be disposed near the second platform 120 (e.g., below the second platform 120 as shown in FIG. 3). The material of the second platform 120 may be suitable for the laser beam L to be transmitted (e.g., the transmittance of the laser beam L is more than 50%; preferably more than 70%; more preferably more than 80%). For example, the material of the second platform 120 may include glass, transparent plastic (e.g., acrylic), but the disclosure is not limited thereto. For another example, the laser beam L may include green light laser or infrared laser, but the disclosure is not limited thereto. The type of the laser beam L and the material of the second platform 120 may be matched with each other, so that the laser beam L generated by the laser generator 161 may be transmitted through the second platform 120.

The form or amount of the laser generator 161 and/or the wavelength range of the laser beam L are not specifically limited by the disclosure, as long as the thermal energy generated by the laser beam L generated by the laser generator 161 irradiating the solder 192 is suitable for melting the solder 192.

Referring to FIG. 3 to FIG. 4, after the electronic component 190 is bonded to the bonded position 182c of the target substrate 182, the actuator mechanism 150 may be actuated to cause the first platform 110 and the second platform 120 to move away from each other.

In this embodiment, after the electronic component 190 is bonded on the bonded position 182c of the target substrate 182, the carrier substrate 181 may be carried on the first platform 110 (at the bottom of FIG. 1 or other similar figures) by the air extraction of the air pump as mentioned above. In this way, in response to the first platform 110 and the second platform 120 moving away from each other, the electronic component 190 bonded on the target substrate 182 may be separated from the carrier substrate 181, so that the electronic component 190 is transferred from the carrier substrate 181 to the target substrate 182.

In an embodiment, the method for transferring an electronic component (e.g., the electronic component 190) may be applied to the manufacture of an LED display. For example, in response to the target substrate 182 being a thin film transistor substrate (e.g., TFT array substrate) and the electronic component 190 being an LED chip, the structure on the second platform 120 shown in FIG. 4 may constitute a part or the entirety of the LED display.

In an embodiment of the disclosure, an apparatus for transferring an electronic component includes a first platform, a second platform, an actuator mechanism, and a flexible push generator. The first platform is configured to carry a carrier substrate. The second platform is configured to carry a target substrate. The actuator mechanism is configured to actuate the first platform and the second platform to approach and move away from each other. The flexible push generator is disposed near the first platform or the second platform and generating a plurality of flexible pushes toward the first platform and the second platform in response to the first platform and the second platform actuated in a way that the first platform and the second platform approach each other.

In an embodiment of the disclosure, the flexible push generator comprises a plurality of parallel air bags.

In an embodiment of the disclosure, the flexible push generator comprises an inflating device, and the inflating device inflates the plurality of parallel air bags.

In an embodiment of the disclosure, the flexible push generator comprises a plurality of parallel air bags, and a cover air bag enclosing the plurality of parallel air bags.

In an embodiment of the disclosure, the flexible push generator comprises an inflating device, and the inflating device inflates the plurality of parallel air bags.

In an embodiment of the disclosure, the apparatus further includes a laser generator. The laser generator is disposed near either the first platform or the second platform and generating a laser beam toward the first platform and the second platform.

In an embodiment of the disclosure, a method for bonding or soldering an electronic component includes the following steps: providing a carrier substrate having a carrying surface on which the electronic component to be bonded is disposed and a non-carrying surface which is opposite to the carrying surface; providing a target substrate having a bonded surface and a non-bonded surface which is opposite to the bonded surface; positioning the carrier substrate and the target substrate with the carrying surface of the carrier substrate facing the bonded surface of the target substrate; making the carrier substrate and the target substrate move toward each other until the electronic component on the carrying surface of the carrier substrate be in contact with the bonded surface of the target substrate; applying a plurality of flexible pushes to the non-carrying surface of the carrier substrate or to the non-bonded surface of the target substrate, in order for the electronic component on the carrying substrate to attain a more complete contact with the bonded surface of the target substrate; and applying a thermal energy to bond the electronic component onto the bonded surface of the target substrate from the carrier substrate.

In an embodiment of the disclosure, the plurality of flexible pushes are applied to the non-carrying surface of the carrier substrate or to the non-bonded surface of the target substrate respectively.

In an embodiment of the disclosure, the plurality of flexible pushes are applied outward from a central portion of the non-carrying surface of the carrier substrate or of the non-bonded surface of the target substrate.

In an embodiment of the disclosure, the plurality of flexible pushes are applied from a side of the non-carrying surface of the carrier substrate or of the non-bonded surface of the target substrate to an opposite side thereto.

In an embodiment of the disclosure, the plurality of flexible pushes are generated by a plurality of air bags.

In an embodiment of the disclosure, the thermal energy is generated by a laser beam.

In an embodiment of the disclosure, the target substrate is a thin film transistor (TFT) substrate.

In an embodiment of the disclosure, the plurality of flexible pushes are applied to the non-bonded surface of the target substrate.

In an embodiment of the disclosure, the thermal energy is applied to the carrier substrate.

In an embodiment of the disclosure, the method further includes the following step: applying a solder to either the electronic component or the bonded surface of the target substrate, prior to applying the thermal energy.

In an embodiment of the disclosure, the electronic component is a light-emitting diode (LED) chip.

In an embodiment of the disclosure, a method for manufacturing an LED display includes the aforementioned method for bonding or soldering an electronic component to bond the LED chip.

To sum up, the apparatus for transferring the electronic component and the method for bonding the electronic component of the disclosure are suitable for transferring the electronic component on the carrier substrate to the target substrate.

What is claimed is:

1. An apparatus for transferring an electronic component, comprising:
a first platform, configured to carry a carrier substrate;
a second platform, configured to carry a target substrate;
an actuator mechanism, configured to actuate the first platform and the second platform to approach and move away from each other; and
a flexible push generator, disposed near the first platform or the second platform and generating a plurality of flexible pushes toward the first platform and the second platform in response to the first platform and the second platform actuated in a way that the first platform and the second platform approach each other.

2. The apparatus for transferring the electronic component according to claim 1, wherein the flexible push generator comprises a plurality of parallel air bags.

3. The apparatus for transferring the electronic component according to claim 2, wherein the flexible push generator comprises an inflating device, and the inflating device inflates the plurality of parallel air bags.

4. The apparatus for transferring the electronic component according to claim 1, wherein the flexible push generator comprises a plurality of parallel air bags, and a cover air bag enclosing the plurality of parallel air bags.

5. The apparatus for transferring the electronic component according to claim 4, wherein the flexible push generator comprises an inflating device, and the inflating device inflates the plurality of parallel air bags.

6. The apparatus for transferring the electronic component according to claim 1, further comprising a laser generator, disposed near either the first platform or the second platform and generating a laser beam toward the first platform and the second platform.

7. A method for bonding an electronic component, comprising:
providing a carrier substrate having a carrying surface on which the electronic component to be bonded is disposed and a non-carrying surface which is opposite to the carrying surface;
providing a target substrate having a bonded surface and a non-bonded surface which is opposite to the bonded surface;
positioning the carrier substrate and the target substrate with the carrying surface of the carrier substrate facing the bonded surface of the target substrate;
making the carrier substrate and the target substrate move toward each other until the electronic component on the carrying surface of the carrier substrate be in contact with the bonded surface of the target substrate;
applying a plurality of flexible pushes to the non-carrying surface of the carrier substrate or to the non-bonded surface of the target substrate, in order for the electronic component on the carrying substrate to attain a more complete contact with the bonded surface of the target substrate;
applying a thermal energy to bond the electronic component onto the bonded surface of the

8. The method for bonding the electronic component according to claim 7, wherein the plurality of flexible pushes are applied to the non-carrying surface of the carrier substrate or to the non-bonded surface of the target substrate respectively.

9. The method for bonding the electronic component according to claim 8, wherein the plurality of flexible pushes are applied outward from a central portion of the non-carrying surface of the carrier substrate or of the non-bonded surface of the target substrate.

10. The method for bonding the electronic component according to claim 8, wherein the plurality of flexible pushes are applied from a side of the non-carrying surface of the carrier substrate or of the non-bonded surface of the target substrate to an opposite side thereto.

11. The method for bonding the electronic component according to claim 7, wherein the plurality of flexible pushes are generated by a plurality of air bags.

12. The method for bonding the electronic component according to claim 7, wherein the thermal energy is generated by a laser beam.

13. The method for bonding the electronic component according to claim 7, wherein the target substrate is a thin film transistor (TFT) substrate.

14. The method for bonding the electronic component according to claim 7, wherein the plurality of flexible pushes are applied to the non-bonded surface of the target substrate.

15. The method for bonding the electronic component according to claim 14, wherein the thermal energy is applied to the carrier substrate.

16. The method for bonding the electronic component according to claim 7, further comprising applying a solder to either the electronic component or the bonded surface of the target substrate, prior to applying the thermal energy.

17. The method for bonding the electronic component according to claim 7, wherein the electronic component is a light-emitting diode (LED) chip.

18. A method for manufacturing an LED display, comprising using the method of claims 17 to bond the LED chip.
